(19) United States
(12) Patent Application Publication
(10) Pub. No.: US 2008/0048324 A1
(43) Pub. Date: Feb. 28, 2008

(54) Fabricating Semiconductor Device

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/844,478

(22) Filed: Aug. 24, 2007

(30) Foreign Application Priority Data
Aug. 24, 2006 (KR) 10-2006-0080548

(51) Int. Cl. H01L 23/52; H01L 21/4763

(52) U.S. Cl. 257/741; 438/610; 257/E21.495; 257/E23.141

(57) ABSTRACT

A method for fabricating a semiconductor device is provided. The method includes: etching an area where a plurality of modules are formed on a semiconductor substrate; forming a plurality of modules on the area; forming on insulation layer on the substrate; forming a plurality of contacts that contact a plurality of the modules by filling a selectively etched area of the isolation layer with conductive material; and forming a first conductive polymer wire for connecting contacts of the plurality of contacts.

### CROSS-REFERENCE TO RELATED APPLICATION

The present application claims the benefit under 35 U.S.C. § 119 of Korean Patent Application No. 10-2006-0080548, filed Aug. 24, 2006, which is hereby incorporated by reference in its entirety.

### BACKGROUND

System On a Chip (SoC) is a semiconductor device fabricated in a form of a chip with various integrated unit modules. For example, an SoC may include various modules, such as a central processing unit (CPU) for processing data and a memory device including DRAM/SRAM/Flash/ROM, integrated on a substrate. However, since each module of the SoC has different design rules according to characteristics and requirements thereof, it is not easy to integrate a plurality of modules in a wafer through the same fabricating process.

Due to this reason, a SoC is generally fabricated by integrating various unit modules together after the unit modules are formed on a printed circuit board (PCB). However, a final semiconductor device thereof becomes enlarged in a size. In order to overcome such a problem, a module area is etched in consideration of an area and a height of each module on a silicon substrate and each module is inserted into each etched area. Then, an insulation layer is deposited, and a post metal wiring process is performed to electrically connect each module, thereby embodying a SoC.

However, the integration of the modules makes the SoC enlarged in size. The size increment of the SoC induces mechanical stress with respect to a metal line used to electrically connect the modules. Such a stress increases the defective proportion of a system.

### BRIEF SUMMARY

Embodiments of the present invention provide a System On a Chip (SoC) including a member for electrically connecting unit modules of the SoC, which has improved characteristics against mechanical stress.

In one embodiment, a method for fabricating a SoC (System on a Chip) includes: etching an area where a plurality of modules are formed on a semiconductor substrate; forming a plurality of modules on the area; forming an insulation layer on the substrate; forming a plurality of contacts that contact a plurality of the modules by filling a selectively etched area of the insulation layer with conductive material; and forming a first conductive polymer wire for connecting contacts of the plurality of contacts.

Since the conductive polymer wire has higher elasticity than a metal line, the conductive polymer wire can effectively endure mechanical stress which becomes greater as the size of a system becomes larger.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of System On a Chip (SoC) according to an embodiment of the present invention.

### DETAILED DESCRIPTION

Reference will now be made in detail to embodiments of the present disclosure, examples of which are illustrated in the accompanying drawings.

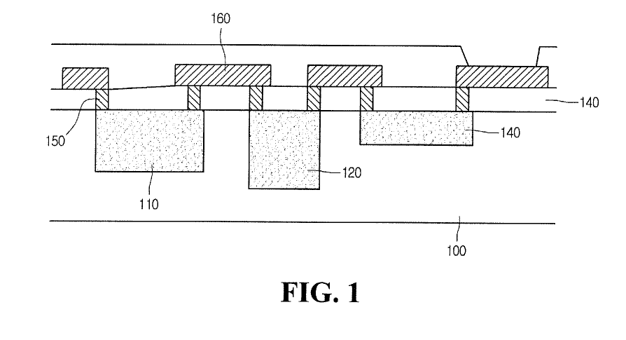

FIG. 1 is a cross-sectional view of System on a Chip (SoC) according to an embodiment of the present invention.

Referring to FIG. 1, the SoC includes a plurality of modules 110, 220, and 230 formed on an etched silicon substrate 100.

Then, an insulation layer 140 is formed on the modules, and contacts 150 are formed by partially etching the insulation layer and filling the etched areas with conductive material.

Then, a wire 160 is formed to connect the contacts 150. In the SoC according to the present embodiment, the wire 160 includes conductive polymer material instead of metal material.

The wire 160 having the conductive polymer material has higher elasticity than a metal line. The higher elasticity enables the wire 160 to sustain a stable shape against mechanical stress that is applied as the size of the system increases. Therefore, it decreases the defective proportion of a system, which is caused by the deterioration of a wire.

Since the polymer material should strengthen the mechanical characteristics of the wire and electrically connect modules, the polymer material should have electrical conductivity similar to or higher than metal material.

Basically, a polymer compound is a nonconductive substance having no electric conductivity. Although a polymer compound has the higher elasticity, the polymer compound has significantly low conductivity like a semiconductor.

However, when an electrical and chemical process delocalizes electron density, the polymer compound can have electric conductivity. Such an electrical chemical process may be a doping process.

Hereinafter, a doping process according to an embodiment of the present invention will be described in detail. When a polymer compound alternatively having a single bond (bond order: 1) and a double bond (bond order: 2) is processed through a doping process, the single bond and the double bond are mixed and combined to have an middle bond length. Therefore, the electrons of the polymer compound become delocalized overall. As a result, the polymer compound obtains an electric conductivity.

In the SoC according to an embodiment, a wire is formed to connect modules after the doping process is performed on a polymer compound having repeated units as shown below.

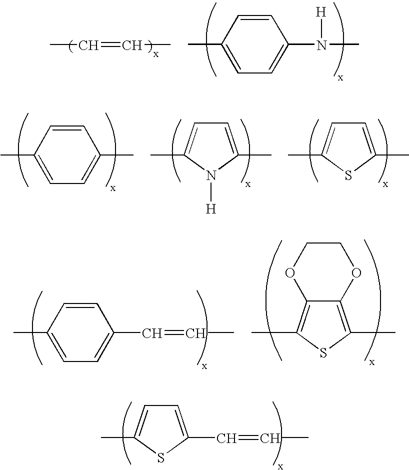

In a method for fabricating a SoC according to another embodiment, an insulation layer 140 made of polymer material can be formed.

Conventionally, the insulation layer 140 is formed using oxide layer material such as BPSG. However, the oxide layer degrades the mechanical characteristics of a device as the system increase like a metal line because the mechanical elasticity of the oxide layer is not good. In the present embodiment, a polymer material having mechanical elasticity and low electric conductivity can be used as the insulation layer 140. The polymer material of the insulation layer strengthens the mechanical characteristics of a device and improves the process flexibility of the system.

Such an insulation layer 140 can be used with a doped polymer compound as a wire 160. Also, the insulation layer 140 allows polymer compounds not having low electric conductivity to be used rather than the described polymer compound used where electric conductivity is needed.

As described above, the SoC formed according to embodiments of the present invention include the wire made of conductive polymer material for connecting the modules. In a further embodiment, the insulation layer can be made of a polymer material not made conductive. Therefore, the SoC can have stable mechanical characteristics although the size of the system increases.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a SoC (System on a Chip) comprising:
etching an area where a plurality of modules are to be provided on a semiconductor substrate;
providing the plurality of modules on the area;
forming an insulation layer on the substrate having the plurality of modules;
selectively etching the insulation layer to expose regions of the plurality of modules;
forming a plurality of contacts by filling the selectively etched insulation layer with conductive material; and
forming a first conductive polymer wire for connecting contacts of the plurality of contacts.

2. The method according to claim 1, wherein the first conductive polymer wire comprises one selected from polymer compounds that have repeated units shown below and high electric conductivity because electron density is delocalized.

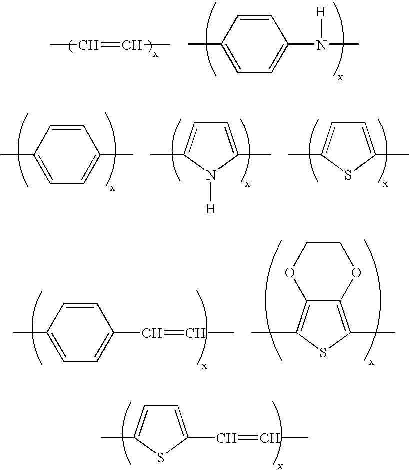

3. The method according to claim 1, wherein the insulation layer comprises a second polymer material having low electrical conductivity.

4. A SoC (System on a Chip) comprising:
a substrate;
a plurality of modules on the substrate and an insulation layer on the substrate including the plurality of modules;
a plurality of contacts connected to the plurality modules through the insulation layer; and
a first conductive polymer wire connecting contacts of the plurality of contacts.

5. The SoC according to claim 4, wherein the first conductive polymer wire comprises one selected from polymer compounds that have repeated units shown below and high electric conductivity because electron density is delocalized.

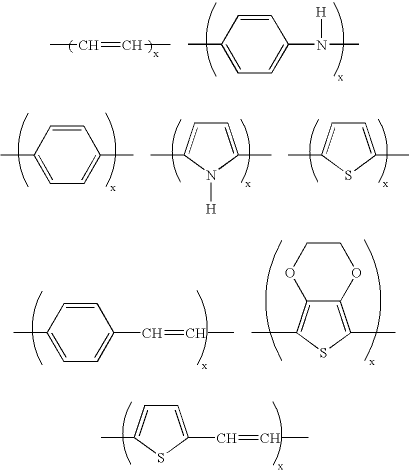

6. The method according to claim 4, wherein the insulation layer comprises a second polymer material having lower electrical conductivity.
